(19) United States
(12) Patent Application Publication
(10) Pub. No.: US 2024/0120336 A1
(43) Pub. Date: Apr. 11, 2024

(54) 3D NANOSHEET STACK WITH DUAL SELECTIVE CHANNEL REMOVAL OF HIGH MOBILITY CHANNELS

(71) Applicant: Tokyo Electron Limited, Tokyo (JP)

(72) Inventors: H. Jim Fulford, Albany, NY (US); Mark I. Gardner, Albany, NY (US)

(73) Assignee: Tokyo Electron Limited, Tokyo (JP)

(21) Appl. No.: 17/962,233

(22) Filed: Oct. 7, 2022

(51) Int. Cl. H01L 27/092; H01L 21/02; H01L 21/8256; H01L 29/06; H01L 29/423; H01L 29/66; H01L 29/775

(52) U.S. Cl. CPC H01L 27/092; H01L 21/02565; H01L 21/02603; H01L 21/8256; H01L 29/0673; H01L 29/42392; H01L 29/66969; H01L 29/775

(57) ABSTRACT

A transistor structure may include a first transistor beside a second transistor. The first transistor can include a first nanosheet oriented horizontally and forming a first channel, a second nanosheet oriented horizontally and forming a second channel, and a first gate structure disposed between and at least partly surrounding the first channel and the second channel. The second transistor can include a third nanosheet oriented horizontally and forming a third channel, a fourth nanosheet oriented horizontally and forming a fourth channel, and a second gate structure disposed between and at least partly surrounding the third channel and the fourth channel. The first nanosheet can be disposed above the third nanosheet, the third nanosheet is disposed above the second nanosheet, and the second nanosheet is disposed above the fourth nanosheet.

### TECHNICAL FIELD

This disclosure related to microelectronic devices including semiconductor 3D devices and design as well as methods of fabrication.

### BACKGROUND

Fabrication of semiconductor devices relies on execution of various fabrication processes that are performed repeatedly in order to form desired semiconductor features on a substrate. In recent years, scaling down semiconductor devices has become more challenging as features sizes have reached the single digit nanometer range.

### SUMMARY

In order to continue scaling down semiconductor devices whose features are in the single digit nanometer range, device structures can be designed vertically with respect to the surface of the substrate. Such devices can be referred to as three-dimensional (3D) semiconductor devices in which transistor structures can be stacked vertically, on top of one another, thus allowing for greater device density per surface area. Fabricating 3D semiconductor devices efficiently, however, can be difficult to achieve for various types of architectures, such as architectures involving NMOS and PMOS nanosheet based transistor structures.

The present solution provides fabrication processes for efficiently fabricating 3D semiconductor NMOS and PMOS devices using nanosheets of different materials along with the resulting 3D nanosheet NMOS and PMOS transistors. The present solution can utilize one epitaxially grown material (e.g., silicon germanium, or SiGe) to form nanosheets for transistor channels on one of a PMOS or an NMOS transistor, while using a different epitaxially grown material (e.g., intrinsic epitaxially grown silicon) to form the channels of the remaining one of the NMOS or a PMOS transistor. The fabrication process of the present solution can rely on selectively removing two channels in each of the PMOS and NMOS layer stacks during the fabrication process and utilize two or more epitaxially grown layers of material. The epitaxially grown materials can include, for example, different types of SiGe layers, such as SiGe layers having different molar ratios of silicon and germanium and layers of intrinsic epitaxial silicon alternating between the SiGe layers. A final capping semiconductor layer of material can include polycrystalline or amorphous semiconductor. The present solution can provide an improved (e.g., higher) mobility for NMOS and PMOS devices using utilizing epitaxially grown material layers in the stack for a more compact transistor (e.g., circuit) design. The present solution can further include any number of stacks (e.g., N-tall) device design using epitaxially grown material layers that can include side-by-side NMOS and PMOS structures. As an option, transistor structures created via wafer bonding can be used as an option to add additional material layers to the stack, or add additional transistor structures, or their components to the resulting structure. Finally, the present solution allows for efficient NMOS and PMOS transistor structure fabrications using a reduced number of process steps, thereby simplifying as well as improving efficiency of the fabrication process.

In some aspects, the present disclosure relates to a transistor structure. The transistor structure can include a first transistor and a second transistor disposed beside the first transistor. The first transistor can include a first nanosheet oriented horizontally and forming a first channel and a second nanosheet oriented horizontally and forming a second channel. The first transistor can include a first gate structure disposed between and at least partly surrounding the first channel and the second channel. The second transistor can include a third nanosheet oriented horizontally and forming a third channel, and a fourth nanosheet oriented horizontally and forming a fourth channel. The third nanosheet can be disposed in a plane that is between a plane in which the first nanosheet is disposed and a plane in which the second nanosheet is disposed. The fourth nanosheet can be disposed in a plane that is beneath the plane in which the second nanosheet is disposed.

The transistor structure can include the first nanosheet of the first transistor disposed above and vertically aligned with the second nanosheet of the first transistor. The transistor structure can include the third nanosheet of the second transistor disposed above and vertically aligned with the fourth nanosheet of the second transistor.

The first transistor of the transistor structure can further include a fifth nanosheet forming a fifth channel. The fifth nanosheet can be disposed in a plane that is beneath the plane in which the second nanosheet is disposed. The fifth nanosheet can be oriented horizontally and vertically aligned with the first nanosheet and with the second nanosheet such that the first, second, and fifth nanosheets have a common footprint. The first gate structure can be disposed between the fifth channel and the second channel and at least partly surrounding the fifth channel.

The second transistor of the transistor structure can further include a sixth nanosheet forming a sixth channel. The sixth nanosheet can be disposed in a plane that is beneath the plane in which the fourth nanosheet is disposed. The sixth nanosheet can be oriented horizontally and vertically aligned with the third nanosheet and the fourth nanosheet. The second gate structure can be disposed between the sixth channel and the fourth channel and at least partly surrounding the sixth channel.

The transistor structure can further include a first gate dielectric of the first gate structure of the first transistor disposed between the first nanosheet and a first gate metal of the first gate structure. The transistor structure can include the first gate dielectric disposed between the second nanosheet and the first gate metal.

The transistor structure can further include a second gate dielectric of the second gate structure of the second transistor disposed between the third nanosheet and a second gate metal of the second gate structure. The transistor structure can include the second gate dielectric disposed between the fourth nanosheet and the second gate metal.

The transistor structure can include the third nanosheet of the second transistor that is horizontally aligned with a portion of the first gate structure of the first transistor that is disposed between the first channel and the second channel. The transistor structure can include the second nanosheet of the first transistor that is horizontally aligned with a portion of the second gate structure of the second transistor that is disposed between the third channel and the fourth channel.

The transistor structure can include the first transistor is one of a p-type metal oxide semiconductor (PMOS) transistor and an n-type metal oxide semiconductor (NMOS) transistor and the second transistor is a remaining one of the PMOS transistor and the NMOS transistor. The transistor structure can include the first transistor and the second transistor that are one of an NMOS transistor or a PMOS transistor.

The transistor structure can include the first nanosheet comprising a shape of a rectangular prism and the first gate structure abutting at least a portion of a top surface of the first nanosheet, a portion of a bottom surface of the first nanosheet and at least a portion of a side surface of the first nanosheet. The transistor structure can include the second nanosheet comprising the shape of the rectangular prism and the first gate structure abutting at least a portion of a top surface of the second nanosheet, a portion of a bottom surface of the second nanosheet and at least a portion of a side surface of the second nanosheet. The transistor structure can include a dielectric structure extending in a vertical trench between the first transistor and the second transistor to electrically isolate the first gate structure of the first transistor from the second gate structure of the second transistor.

In some aspects, the present disclosure relates to a method. The method can be a method for fabricating a nanosheet-based NMOS and PMOS transistor structure. The method can include forming a first transistor by horizontally forming a first nanosheet to form a first channel, and horizontally forming a second nanosheet to form a second channel. The method can include forming a first gate structure of the first transistor. The first gate structure can be disposed between the first channel and the second channel and at least partly surrounding the first channel and the second channel. The method can further include forming a second transistor by horizontally forming a third nanosheet to form a third channel of a second transistor disposed beside the first transistor and horizontally forming a fourth nanosheet to form a fourth channel. The method can include forming a second gate structure of the second transistor. The second gate structure can be disposed between the third channel and the fourth channel and at least partly surrounding the first channel and the second channel. The third nanosheet can be is disposed in a plane that is between a plane in which the first nanosheet is disposed and a plane in which the second nanosheet is disposed. The fourth nanosheet can be disposed in a plane that is beneath the plane in which the second plane is disposed.

The method can include forming the first transistor by disposing the first nanosheet above the second nanosheet and vertically aligning the first nanosheet with the second nanosheet. The method can further include forming the second transistor by disposing the third nanosheet above the fourth nanosheet and vertically aligning the third nanosheet with the fourth nanosheet.

The method can further include forming the first transistor by horizontally forming a fifth nanosheet to form a fifth channel of the first transistor. The fifth nanosheet can be disposed in a plane that is beneath the plane in which the second nanosheet is disposed. The method can include vertically aligning the fifth nanosheet with the first nanosheet and with the second nanosheet. The method can further include forming the first gate structure between the fifth channel and the second channel and at least partly surrounding the fifth channel.

The method can further include forming the second transistor by horizontally forming a sixth nanosheet to form a sixth channel. The sixth nanosheet can be disposed in a plane that is beneath the plane in which the fourth nanosheet is disposed. The method can further include vertically aligning the sixth nanosheet with the third nanosheet and the fourth nanosheet. The method can include forming the second gate structure between the sixth channel and the fourth channel and at least partly surrounding the sixth channel.

The method can further include forming a first gate dielectric of the first gate structure. The first gate dielectric can be disposed between the first nanosheet and a first gate metal of the first gate structure. The method can include forming the first gate dielectric disposed between the second nanosheet and the first gate metal.

The method can further include forming a second gate dielectric of the second gate structure. The second dielectric can be disposed between the third nanosheet and a second gate metal of the second gate structure. The method can include forming the second gate dielectric disposed between the fourth nanosheet and the second gate metal.

The method can further include forming the third nanosheet of the second transistor in a horizontal alignment with a portion of the first gate structure of the first transistor disposed between the first channel and the second channel. The method can include forming the second nanosheet of the first transistor in a horizontal alignment with a portion of the second gate structure of the second transistor disposed between the third channel and the fourth channel.

These and other aspects and implementations are described in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the present disclosure can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 is a cross-sectional illustration of an example an NMOS and a PMOS, side-by-side transistor structure formed using horizontal nanosheets disposed at alternating heights between the two transistors, according to one or more embodiments.

FIGS. 2A-2B depict cross-sectional illustrations of an example layer stack used to form a layer stack structure in which the transistor structure of the present solution is to be formed, according to one or more embodiments.

FIGS. 3-21 depict cross-sectional and top-down illustrations of example fabrication flow steps for manufacturing a transistor structure of the present solution, according to one or more embodiments.

FIG. 22 is a flow diagram of an example method for fabricating transistor structures in accordance with the present solution and using techniques and features of the fabrication steps discussed and illustrated in connection with FIGS. 1-21, according to one or more embodiments.

### DETAILED DESCRIPTION

Reference will now be made to various illustrative embodiments depicted in the drawings, and specific language will be used to describe the same. It is understood that no limitation of the scope of the claims or this disclosure is thereby intended. Alterations and further modifications of the inventive features illustrated herein, and additional applications of the principles of the subject matter illustrated herein, which would be apparent to one of ordinary skill in the relevant art having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

It is understood that apparatuses, systems, and devices produced by the structures described herein can be used or find their application in any number of electronic devices utilizing structures and/or circuits described herein, such as for example, controllers, memory chips, systems or process on a chip processors, graphics processing units, central processing units, integrated circuits and more. For example, structures and/or circuits described herein can include a part of systems including or utilizing memory, such as any computing systems including for example: computers, phones, servers, cloud computing devices, and any other device or system that utilizes integrated circuit devices.

The embodiments described herein may enable an increased stack height of one or more 3D semiconductor devices. Therefore, a semiconductor substrate can be used, but is not required, and any base layer material (e.g., glass, organic, etc.) may be used instead of a silicon substrate. A base layer, therefore, can be a semiconductor substrate, such as a silicon substrate or any other semiconductor, ceramic, metal or other material substrate.

The process flows described herein can utilize conductive dielectric materials to form NMOS and PMOS devices. As such, the techniques described herein can be used to produce devices that are manufactured, or “stacked” on any existing vertically stacked device or substrate, according to various implementations. The present techniques may improve upon other semiconductor manufacturing techniques by increasing the N height of stacked semiconductor devices, such as transistors, thereby providing high density logic. Although illustrations herein may show an NMOS device arranged over a PMOS device, or an NMOS device arranged beside a PMOS device, alternative configurations are contemplated. Alternative configurations can include a PMOS device over NMOS device, NMOS device over NMOS device, PMOS device over PMOS device, PMOS beside NMOS device, NMOS beside NMOS device, PMOS beside PMOS device or other alternative including one or more NMOS devices or PMOS devices for any number of N stacks and in any order or arrangement.

Dielectric materials used herein can be any material or materials having low electrical conductivity, such as for example one millionth of a mho/cm. Dielectric materials can include, for example, silicon dioxide, silicon nitride, nanoporous silica, hydrogensilsesquioxanes (HSQ), Teflon-AF (Polytetrafuoethene or PTFE), Silicon Oxyfluoride. Dielectric materials can also include, for example, ceramics, glass, mica, organic and oxides of various metals.

A high-k dielectric, also referred to as high-k material, can refer to any material with a higher dielectric constant as compared to the silicon dioxide. For example, high-k dielectric can include hafnium silicate, zirconium silicate, hafnium dioxide, zirconium dioxide, and others.

Various metals, such as gate metal and the source/drain metal, can be used herein and can include any metal or any electrically conductive material. For example, metals used in the present solution can include aluminum, copper, titanium, ruthenium, titanium, tungsten, silver, gold or any other metal. For the purposes of the present solution, in addition to the metals, source/drain metals or gate metals can also include other electrically conductive materials, such as highly doped semiconductors, for example.

The present solution can also utilize 2D materials for forming transistor channels. 2D materials can include, for example, but are not limited to, WS2, WSe2, WTe2, MoS2, MoSe2, MoTe2, HfS2, ZrS2, and TiS2, GaSe, InSe, phosphorene, and other similar materials. These materials can be deposited by an atomic layer deposition (ALD) process and may be about 5-15 angstroms thick, the thinness lending to their name −2D material. 2D material layer can, depending on the material and design, and can have a broader range of thicknesses, such as between 0.2 nm and 3 nm, for example. 2D materials may be annealed during or after the device formation process to recrystallize or grow the crystals and thereby improve electrical characteristics. 2D materials, for example, can be electrically conductive. For example, a 2D material can be deposited on an outer surface of a nanosheet to form a transistor channel supported by the nanosheet.

Additionally or alternatively, 2D materials to be used for forming 2D channels may comprise one or more semiconductive-behaving materials, which may be formed using certain elements that, when combined with oxygen, form a new material that exhibits semiconductive behavior. For example, the semiconductive behaving material can be “turned off” and can have a low or practically no off-state leakage current, and can be “turned on” and become highly conductive when voltage is applied. Example materials to create an n-type channel for example include, but are not limited to, In2O3, SnO2, In GaZnO, and ZnO. Example materials that can be used to create a p-type channel may be formed utilizing, for example, SnO. These materials may be further doped to improve the electrical characteristics. These materials may also be referred to as conductive oxides or semiconductive behaving oxides for the purposes of this discussion.

As 2D materials can have a very large mobility, they can be herein described as one embodiment, however it is to be appreciated that other non-epitaxially grown materials can be utilized. Since a 2D material can be precisely deposited on an insulative sheet, this can enable a very low Dt integration build of horizontal nanosheets with high performance. Advantageously, any base substrate material can be utilized as no epitaxial growth is required and the base substrate can be removed for further stacking of the devices.

Carrier nanosheets can be used to provide support for the 2D material layers. Carrier nanosheets can include dielectric materials or semiconductor materials on which 2D material layer, such as a monolayer of 2D material, can be deposited, grown or otherwise formed. Carrier nanosheet can include an electrically insulating material that can be used as a seed layer for the 2D material(s) used in the stack. Carrier nanosheets can, in some implementations, include the materials suitable for forming a transistor channel using the nanosheet material which can include doped semiconductor material. Additionally or alternatively, a seed layer can include a material that can be deposited onto a carrier nanosheet, onto which a layer of 2D material can be formed, deposited or applied.

The present disclosure can also refer to conductive oxide materials. Conductive oxides can include certain types of materials that include elements combined with oxygen to form a new material that exhibits semiconductor properties, including being able to turn off with low off state leakage current under some conditions and be highly conductive under other conditions. For example, N type conductive channels can be formed with In₂O₃, SnO₂, InGaZnO and ZnO. P type conductive channels can be formed with SnO. Using these materials, N-type and P-type transistors can be formed using conductive oxides. In some instances, conductive oxides can be used instead of or together with 2D materials, and vice versa.

The order of description or fabrication steps performed or described herein has been presented for clarity sake and as an example. The fabrication steps described herein can be performed in any suitable order. Fabrication can be included, for example, using wafer bonding techniques in which a portion of a layer stack or a transistor structure can be bonded with another portion of a layers tack or a transistor structure on another wafer utilizing any number of techniques. Additionally, although each of the different features, techniques, configurations described herein may be described in different places of this disclosure, it is intended that each of the concepts can be executed independently of each other or in combination with each other. Accordingly, the solutions described herein can be embodied and viewed in many different ways.

Reference will now be made to the Figures, which for the convenience of visualizing the 3D semiconductor fabrication techniques described herein, illustrate an example substrate and its deposited material layers undergoing a process flow in both top and cross-sectional views. Unless expressly indicated otherwise, each Figure represents one (or a set) of fabrication steps in an example process flow that can be used for manufacturing the devices produced by the present solution. In the top and cross-sectional views of the Figures, connections or interfaces between conductive layers or materials may be shown. However, it should be understood that these connections or interfaces between various layers and masks are merely illustrative, and are intended to show a capability for providing such connections, and they should not be considered limiting to the scope of the claims. Conversely, when example illustrations do not show electrical connections to components that are electrically contacted, it is understood that such electrical connections can be made as understood by a person of ordinary skill.

Although the Figures and aspects of the disclosure may show or describe devices herein as having a particular shape, it should be understood that any illustrated shapes, whether of the structures or features, are used as examples of the present solution and are merely illustrative and should not be considered limiting to the scope of the techniques described herein. For example, although most of the Figures can show various layers in a rectangular shaped configuration, other shapes are also contemplated, and indeed the techniques described herein may be implemented in any shape or geometry, such as circular, elliptical, or any curved or any polygonal shape. In addition, examples in which a particular number of transistors or nanosheets are shown stacked on top of one another are shown for illustrative purposes only, and for the purposes of simplicity. Indeed, the techniques described herein may provide for one to any number N stacked transistors or nanosheets. Further, although the devices fabricated using these techniques are shown as transistors, it should be understood that any type of electronic device may be manufactured using such techniques, including but not limited to transistors, variable resistors, resistors, capacitors, memory components, logic gates and components and any other components known or used in the art.

Despite the fact that illustrated embodiments for simplicity and brevity show examples of only a single or double transistor structures being formed using the techniques of the present solution, any number of transistors can be formed above and beside the transistor structures illustrated in examples illustrated, such as may be desired for forming a 3D array of devices. For example, a plurality of PMOS and NMOS devices can be fabricated, using the techniques discussed herein, in a plurality of rows and columns on a substrate and a plurality of stacks of PMOS and NMOS devices can be stacked on top of such rows and columns of NMOS and PMOS devices.

Embodiments herein relate to fabrication of PMOS and NMOS transistors using epitaxially grown material layers. Epitaxially grown material layers can include various types of SiGe material layers, intrinsic epitaxially grown silicon layers, poly silicon layers and others. For example, illustrated embodiments can discuss semiconductor device fabrication utilizing a layer stack that can include layers ordered as: SiGe 2 layer/SiGe 3 layer/Si layer/SiGe layer/Si/SiGe/Si/SiGe and a polysilicon layer. It is understood that other combinations of epitaxially grown layers with similar material characteristics and similar material properties can be used for the present disclosure. For example, a general structure can include epitaxial layer 2/epitaxial layer 3/epitaxial layer 1/epitaxial layer 3/epitaxial layer 1 and so on, provided that these layers allow for similar selective processing, such as for example selective etching, as is performed in the illustrated embodiment. Therefore, it is understood that the present solution is contemplated to apply to more than just the list of materials used as examples in the illustrated embodiments.

The present solution can provide side-by-side NMOS and PMOS devices, in which each of the NMOS and PMOS device includes multiple horizontal nanosheets. In the present solution, the same material layers that form nanosheets in a first transistor device (e.g., NMOS) can act as sacrificial layers in the second device (e.g., the PMOS device) that can be formed beside the first transistor. In such a solution, the same material layers that form nanosheets for transistor channels in a first transistor device can act as sacrificial layers between the nanosheets forming channels in the second transistor. Likewise, the same material layers that forms nanosheets for transistor channels in the second transistor device can act as sacrificial layers between the nanosheets forming channels in the first transistor. This can result in each of the nanosheets (or channels) in both (e.g., PMOS and NMOS) devices to be disposed in a different horizontal plane than any other horizontal plane in which any other horizontal nanosheets (or channels) in the two side-by-side transistor devices are disposed. The present solution can also provide the NMOS and PMOS devices in which the nanosheets of the NMOS device can include a different material than the material included in the nanosheets of the PMOS device.

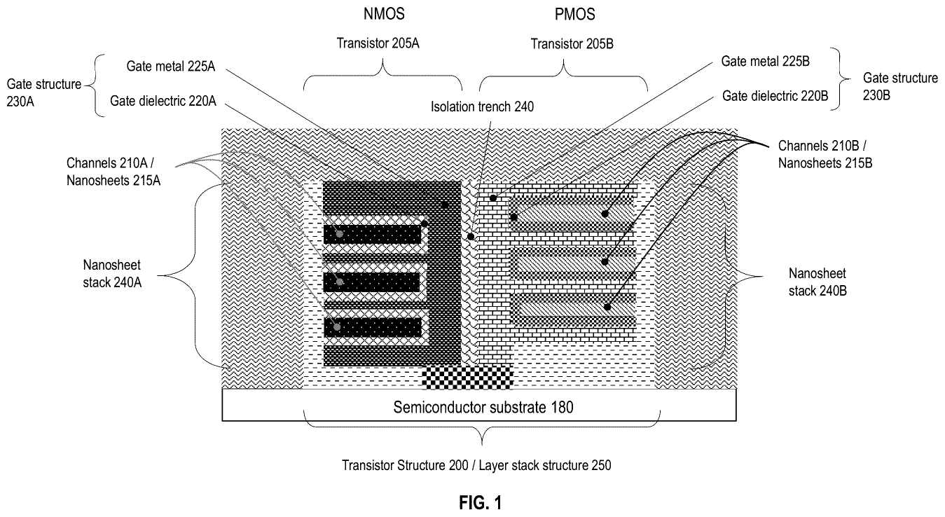

Prior to describing the fabrication steps for manufacturing the structures of the present solution, it may be useful to first briefly overview an example side-by-side 3D NMOS and PMOS structure fabricated in accordance with the methods and techniques of the present solution. As an illustrative example, FIG. 1 includes a cross-sectional view of transistor structure 200 that can include an NMOS transistor 205A and a PMOS transistor 205B can be fabricated on a semiconductor substrate 180 using the process techniques described herein applied to the layer stack structure 250. One the left side of the transistor structure 200, in the nanosheet stack 240A, transistor 205A can include three channels 210A formed using three nanosheets 215A. Each channel 210A of transistor 205A can be formed based on and using its own corresponding nanosheet 215A. Each channel 210A can be surrounded by a gate structure 230A, which can include a gate dielectric 220A that is surrounded by gate metal 225A. Likewise, one the right side of the transistor structure 200, in the nanosheet stack 240B, transistor 205B can include three channels 210B formed using three nanosheets 215B. Each channel 210B of transistor 205B can be formed based on and using its own corresponding nanosheet 215B. Each channel 210B can be surrounded by a gate structure 230B, which can include a gate dielectric 220B that is surrounded by gate metal 225B.

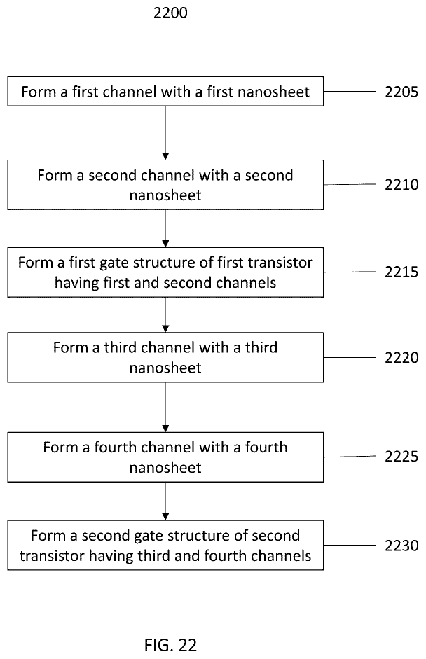

As will be further described below, the material layers used to form nanosheets 215A in transistor 205A can act as sacrificial layers for areas of transistor 215B that are in between the nanosheets 215B of the transistor 205B. At the same time, the material layers used to form nanosheets 215B in transistor 205B can act as sacrificial layers for areas in between nanosheets 215A in transistor 205A. As a result, each one of the nanosheets 215A and 215B in the transistor structure 200 can be disposed in different horizontal planes with respect to all other nanosheets in the transistor structure 200. For example, as depicted in FIG. 22, the top channel 210B of transistor 205B that is formed using the top horizontal nanosheet 215B is disposed above the top channel 210A of transistor 205A. Similarly, the top channel 210A of transistor 205A is disposed above the middle channel 210B that is formed using the middle nanosheet 215B in transistor 205B. Similarly, the middle channel 210B of transistor 205B is disposed above the middle channel 210A of transistor 205A, while the middle channel 210A of transistor 205A is disposed above the bottom channel 210B that is formed using the bottom nanosheet 215B in transistor 205B. Likewise, the bottom channel 210B of transistor 205B is disposed above the bottom channel 210A that is formed using the bottom nanosheet 215A in transistor 205A. Therefore, channels 210A and 210B (and their corresponding nanosheets 215A and 215B) are alternating with each other in terms of their individual heights, since each channel 210A or 210B (and each nanosheet 215A and 215B) is disposed at its own height level or its own individual horizontal plane in the transistor structure 200.

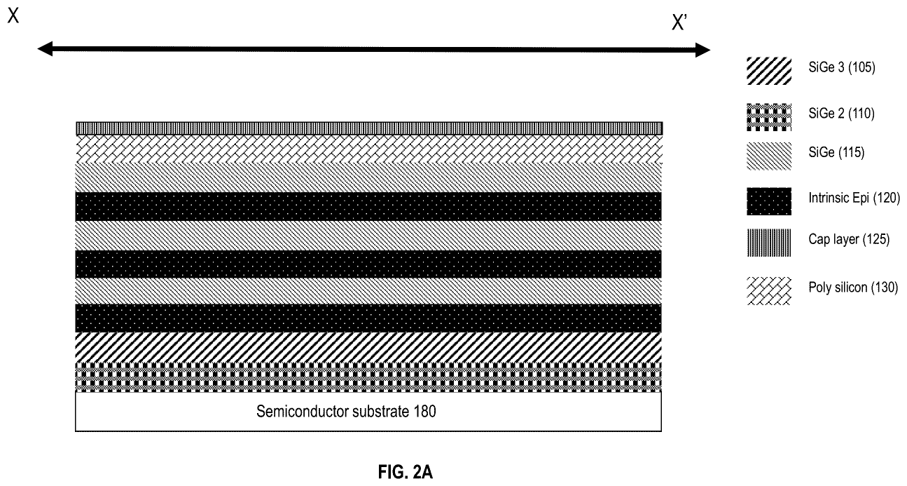

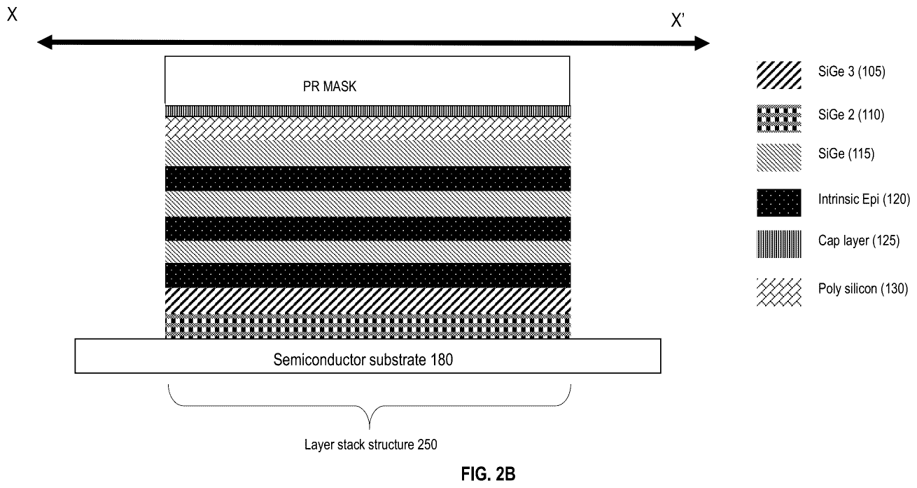

Referring not to the start of the fabrication process of the transistor structure 200, FIG. 2A refers to an initial stack of material that can be used for fabricating transistor structure 200. FIG. 2A depicts a cross-sectional view of an example layer stack having several layers of materials. The layer stack can be formed on a substrate 180. The layer stack can include multiple material layers deposited on top of each other. For example, a first layer of material deposited on a substrate 180 can include a layer of SiGe 2 (identified in the illustration as material SiGe 110). On top the first material layer of SiGe 110, a layer of SiGe 3 (identified in the illustration as material SiGe 105) can be deposited. On top of the SiGe 105, a layer of intrinsic epi material (identified in the illustration as intrinsic epi 120), can be deposited. Intrinsic epi 120 can include, for example, an epitaxial silicon intrinsic layer and can be referred to as an intrinsic epitaxially grown silicon layer. Intrinsic epi 120 can include a non-doped, and therefore resistive, silicon material. Alternatively or additionally, intrinsic epi 120 can include doped, and therefore, conductive or semi-conductive material. On top of the intrinsic epi 120, a first layer of SiGe material (identified in the illustration as material SiGe 115) can be formed. Like intrinsic epi 120, SiGe 115 can also include non-doped or doped material. On top of the first layer of SiGe 115, a second layer of intrinsic epi 120 can be deposited, followed by a second layer of SiGe 115, which can then also be followed by a third layer of intrinsic epi 120 layer, which can also be followed by a third layer of SiGe 115. As a result, a total of six layers of intrinsic epi 120 and SiGe 115 materials that are layered on top of each other in an alternating fashion, such that each two SiGe b layers are separated by a layer of intrinsic epi 120 and each two intrinsic epi layers 120 are separated by a layer of SiGe 115. On top of the third SiGe 115 layer, a layer of poly silicon (identified in the illustration as poly silicon 130) can be deposited, on top of which a cap layer (identified in the illustration as cap layer 125) can be deposited to complete the layer stack of materials from which the transistor structure 200 is to be fabricated.

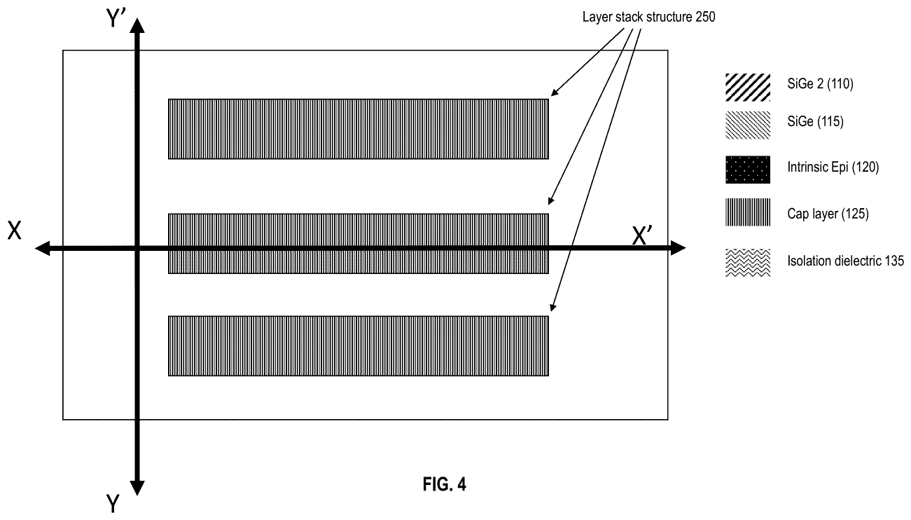

FIG. 2B illustrates a cross-sectional view of the layer stack on top of which a photoresist (PR) mask is applied to perform an etch. The PR mask can protect and shape the layer stack structure 250 in which transistor structure 200 is to be fabricated. The layer stack structure 250 can be formed by etching out the surrounding material using the directional etch of the areas not protected by the PR mask. After the PR mask is layered on top of the layer stack, an etch, such as a directional downward etch, can be performed outside of the PR mask to define the initial X-Y dimensions of the layer stack portion in which the 3D transistor structure 200 is to be formed. The Y dimensions of the layer stack can be visible, for example, in the top view of FIG. 4, illustrated and discussed below.

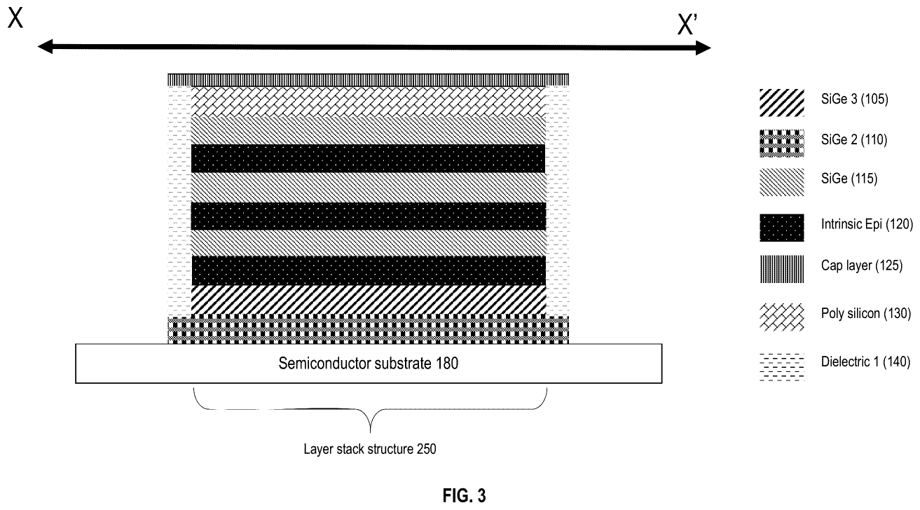

FIG. 3 illustrates a cross-sectional view of the layer stack following the completion of several fabrication steps. First, a photoresist strip can be performed to remove the PR mask illustrated in FIG. 2B. After the photoresist strip, an indent etch of poly silicon 130, SiGe 115 and/or intrinsic epi 120 (e.g., silicon) layers can be performed. The indent etch can be performed simultaneously on the outer surfaces of the portions of poly silicon 130, SiGe 115 and instrinsic epi 120 layers that are exposed on the sidewalls of the layer stack portion created by etching in connection with FIG. 2B. In some embodiments, only SiGe 115 and intrinsic epi 120 layers can be indent etched, while poly silicon 130 may be not etched. The indent etch be performed upon the layers of poly silicon 130, SiGe 115 and/or intrinsic epi 120 silicon material from the openings on the sides of those material layers, from the direction of the etched out trenches at the distal ends of the layer stack structure 250. The indent etch can remove the outer portions of material layers of each of the poly silicon 130, SiGe 115 and intrinsic epi 120, until the layers of those three materials are indented. The indented etched layers can be made shorter by some fraction of their total horizontal length with respect to the cap layer 125 and SiGe 110 layer, which are not etched.

Following the indent etch of the poly silicon 130, SiGe 115 and intrinsic epi 120, a deposition fill can be performed by dielectric 1 (identified in the illustration as dielectric 140). The deposition fill by dielectric 140 can fill in the indent etched portions of the poly silicon 130, SiGe 115 and intrinsic epi 120 layers. Once the trench is filled with the dielectric 140 material, a downward directional etch can be performed using the cap layer 125 as the mask in order to fill the incident etched portion (e.g., indent etch portion) of the layer stack with dielectric 140. As a result, the material layers of SiGe 115 and intrinsic epi 120 inside the layer stack structure 250 can be completely surrounded by dielectric 140. For example, indent etch of the SiGe 115 and intrinsic epi 120 layers can be performed on all four sides of the layer stack structure 250, after which dielectric 140 layer can be deposited on all four sides of the SiGe 115 and intrinsic epi 120 layers. Once the layer stack structure 250 is processed into the final transistor structure 200 these SiGe 115 and intrinsic epi 120 layers can be electrically isolated on their outer surfaces by the dielectric 140 wall (e.g., vertical structure) that surround these layers on the outer surfaces.

FIG. 4 illustrates a top-down view of the layer stack following the completion of fabrication steps described in FIG. 3. As shown in FIG. 4, from a top-down perspective multiple rectangular shapes exposing cap layer 125 material can indicate multiple 3-D rectangular prismatic layer stack structures 250 in which multiple transistors 205A and 205B are to be formed in the upcoming steps. The X-axis illustrates a point of cross-section in the illustrated cross-sectional views, while Y axis shows that beside the layer stack structure 250 that is cross-sectioned in the illustrated example, other same or similar layer stack structures 250 can be provided which other PMOS and NMOS transistors 205 are to be formed simultaneously.

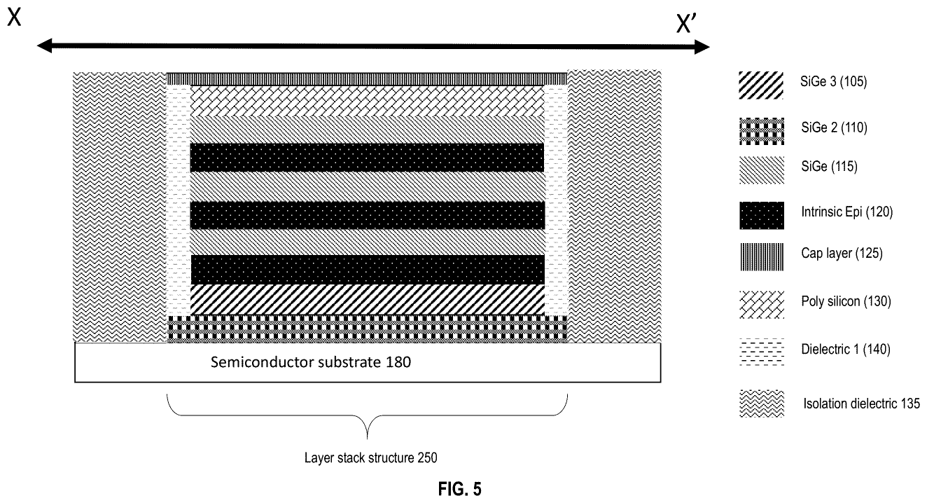

FIG. 5 illustrates a cross-sectional view of the layer stack structure 250 completing an isolation deposition by filling the etched out trench around the layer stack structure with isolation dielectric 135. This step can be followed by a chemical mechanical planarization or polishing (CMP), to remove all the surplus material above the cap layer 125.

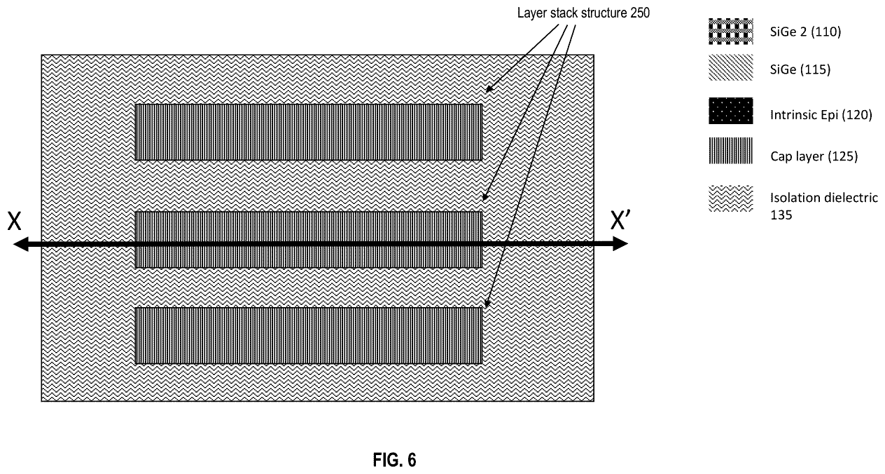

FIG. 6 illustrates a top-down view of the layer stack structures 250 following the completion of the fabrication steps described in FIG. 5. As shown in FIG. 6, rectangular shapes of cap layers 125 shown earlier in FIG. 4 are now surrounded by isolation dielectric 135. At this point, layer stack structures in which transistors are to be formed are buried in isolation dielectric 135 material, whose top surface can be made flush with the cap layer 125 of the layer stack.

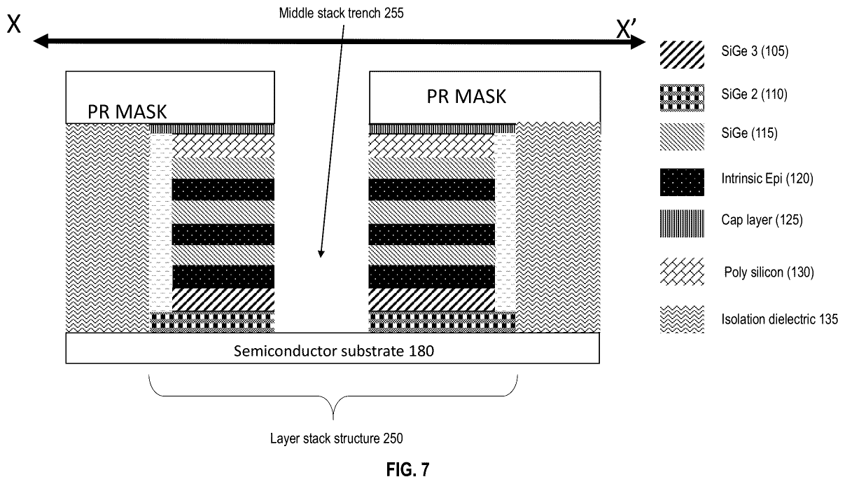

FIG. 7 illustrates a cross-sectional view in which a PR mask is applied, covering the two end portions of the layer stack structure 250, and exposing the middle portion of the layer stack structure 250 in which a downward etch is to be performed. For example, a PR mask can cover a middle portion of the layer stack structure 250 that corresponds to a fraction of the length the layer stack structure 250, such as a fifth, a quarter, a third or a half of the length of the layer stack structure 250, exposing the middle portion for etching. A directional downward etch can then be performed through the entire exposed middle portion of the layer stack structure 250 until semiconductor substrate 180 is reached. The etched out middle portion can result in a vertical middle stack trench 255 that is formed the middle section of the layer stack structure 250.

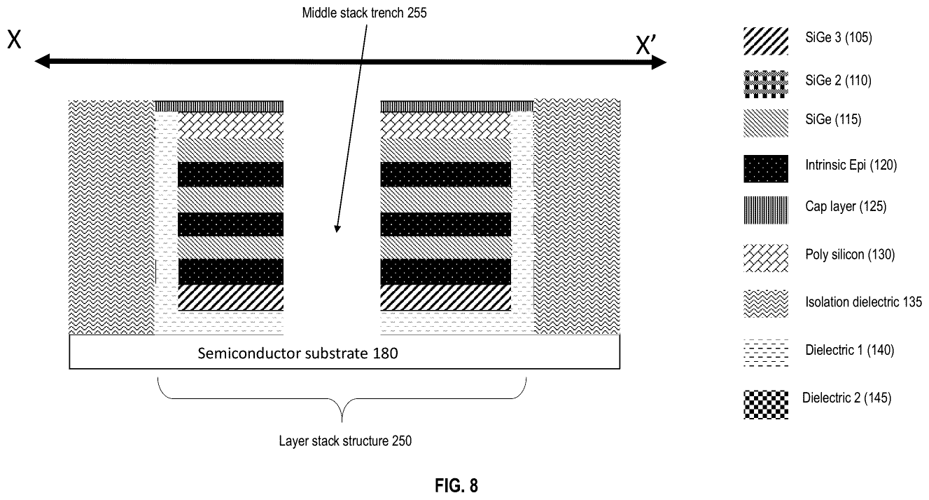

FIG. 8 illustrates a cross-sectional view of the layer stack in which SiGe 110 material at the bottom layer (e.g., the first SiGe 110 layer on top of the semiconductor substrate 180) is removed. Removal of SiGe 110 can be implemented by selectively etching of SiGe 110 through the middle stack trench 255 created in connection with FIG. 7. The empty space left where SiGe 110, can be filled in by dielectric 140 material.

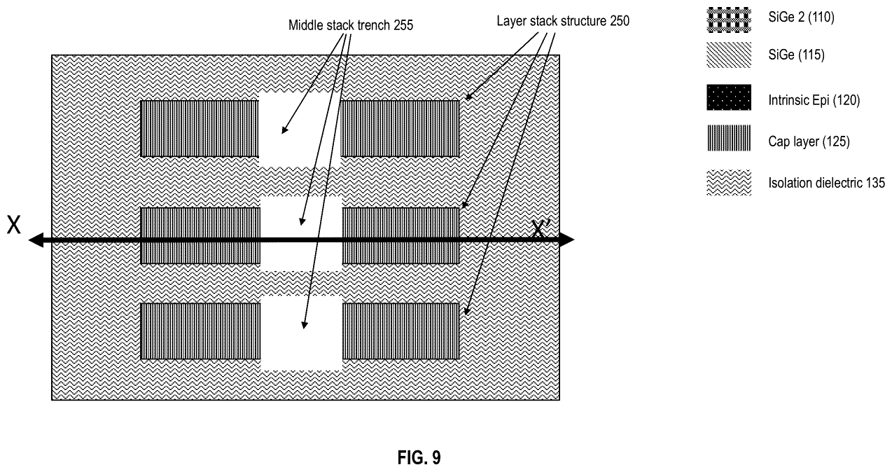

FIG. 9 illustrates a top-down view of the layer stack following the completion of the fabrication steps described in FIG. 8. As shown in FIG. 9, middle stack trenches 255 are directionally etched downward through the middle portion of the layer stack structures 250 indicated by the cap layers 125 rectangular structures. As illustrated, middle stack trenches 255 can be etched through the entire layer stack structures 250 but can also extend partially into isolation dielectric 135 surrounding material. This can ensure isolation between one side of the layer stack structure 250 and the other side of the layer stack structure 250.

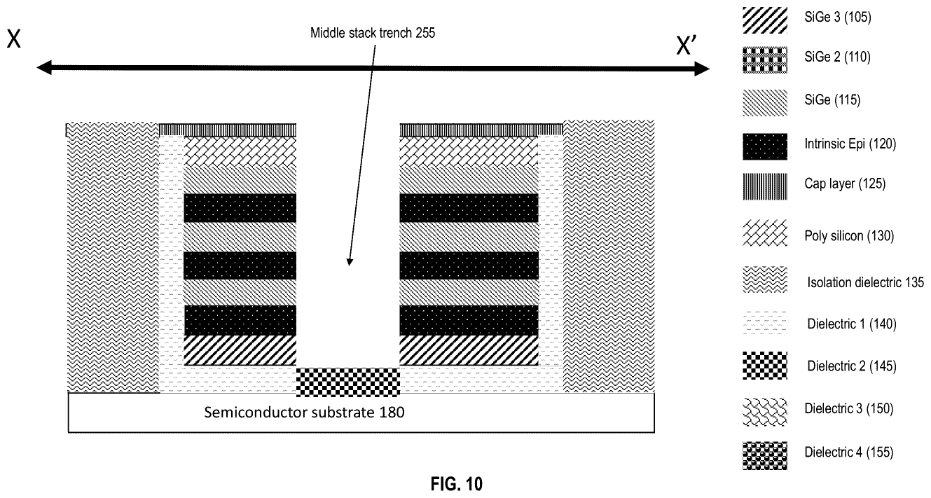

FIG. 10 illustrates a cross-sectional view of the layer stack in which dielectric 2 (identified in the illustration as dielectric 145) is deposited at the bottom layer to fill in the space inside the middle stack trench 255 in which SiGe 110 material used to be deposited. Dielectric 145 can then fill out the space on top of the substrate 180 and up to the bottom surface of the SiGe 105 layer. Upon completion of this step, a CMP can be performed.

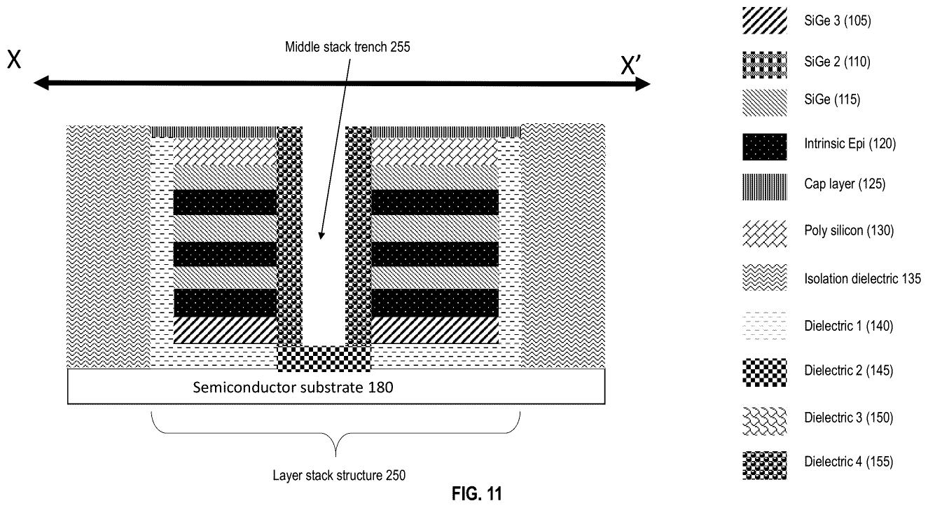

FIG. 11 illustrates a cross-sectional view of the layer stack in which dielectric 4 (identified in the illustration as dielectric 155) is deposited on the sidewalls of the middle stack trench 255. A layer of dielectric 155 can be deposited all around the interior cavity of the middle stack trench 255, coating the interior sidewalls of the SiGe 115 and intrinsic epi 120 layers formed by the trench. The central portion of the middle stack trench 255 can remain empty (e.g., hollow), separating the two sides of the layer stack structure 250.

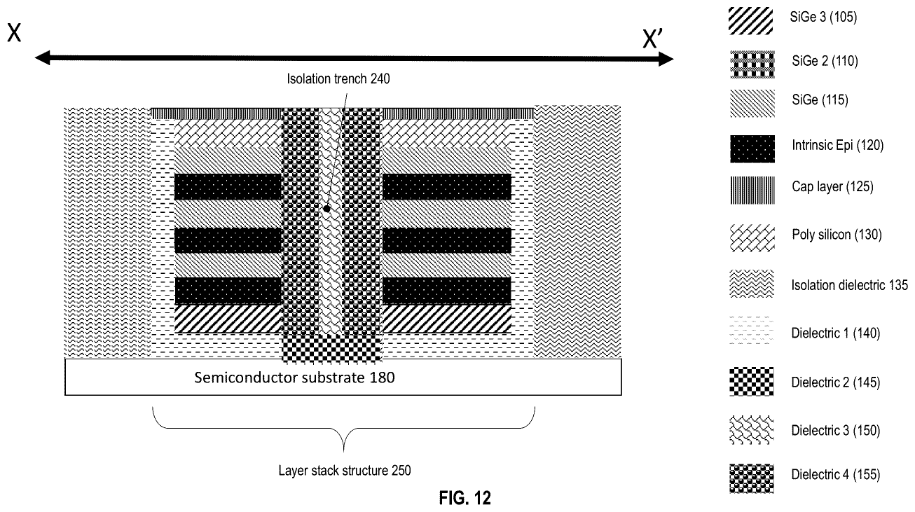

FIG. 12 illustrates a cross-sectional view of the layer stack in which dielectric 3 (identified in the illustration as dielectric 150) is deposited in the central portion to fill the hollow cavity formed by the sidewalls created by dielectric 155 deposited in connection with FIG. 11. Once the central portion of the cavity (e.g., in between the sidewalls created by dielectric 155) is filled with dielectric 150, a CMP can be performed to remove the surplus material. The resulting vertical filling with dielectric 150 material forms the isolation trench 240 that is going to separate transistors 205A and 205B once they are formed to the left and to the right of the isolation trench 240, respectively.

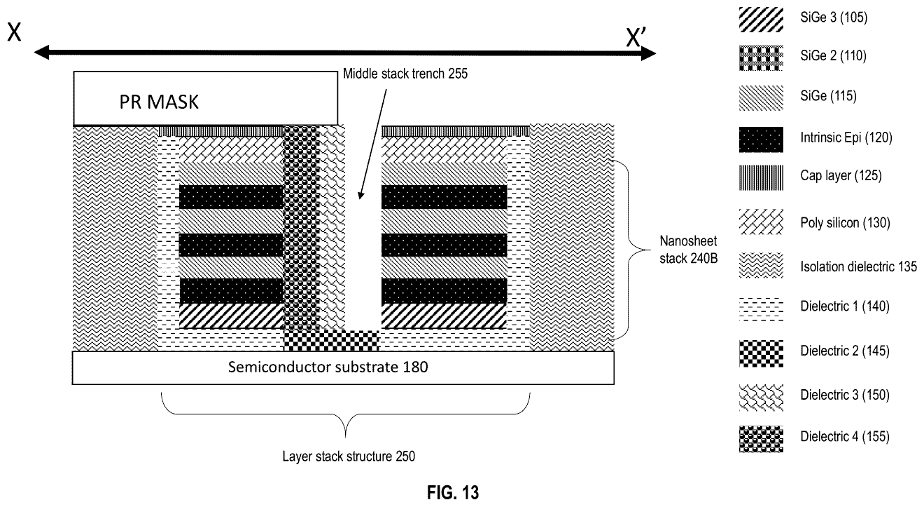

FIG. 13 illustrates a cross-sectional view of the layer stack in which dielectric PR mask can be placed on one side (e.g., left side) of the layer stack structure 250 in order to clear out the exposed part (e.g., the right side) of the middle stack trench 255. A vertical etch downward can clear out the dielectric 155 on the exposed (e.g., right) side of the middle stack trench 255. This can open up or expose the right side nanosheet stack 240B and therefore expose the SiGe 115 and intrinsic epi 120 layers on the right side of the layer stack structure 250 for further processing through the cleared out portion of the middle stack trench 255.

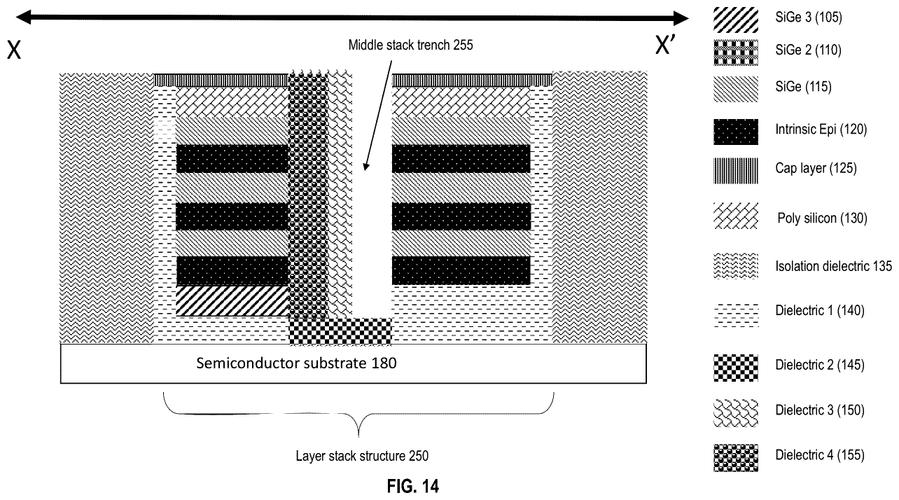

FIG. 14 illustrates a cross-sectional view of the layer stack in which dielectric PR mask is removed and then SiGe 105 layer is removed on the right side of the layer stack structure 250 beneath the first layer of intrinsic epi 120. SiGe 105 can removed via selective etch of SiGe 105 material through the opening in the middle stack trench 255 created in FIG. 13. Once removed, the space that was previously filed by SiGe 105 (on the right side of the SiGe 105 layer) can be filled with dielectric 140 material. Dielectric 140 can be fill deposited through the same opening (e.g., as created in FIG. 13) and then CMP can be performed to remove the surplus material. Then, an etch aligned to the hardmask (e.g., in line with the vertical opening defined by dielectric 150 and cap layer 125 on the right side) can be performed vertically downward to complete the interior side surfaces of the right-side 3D nanosheet stack 240B

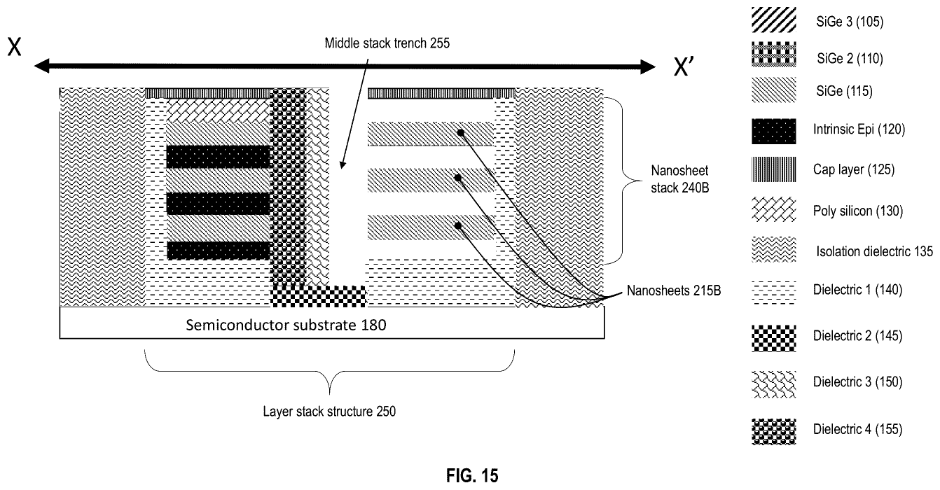

FIG. 15 illustrates a cross-sectional view of the layer stack structure 250 in which the right side portion of the intrinsic epi 120 layer and poly silicon 130 is removed from the right-side 3D nanosheet stack 240B. Intrinsic epi 120 and poly silicon 130 can be removed via selective etching process directed to these and which can be implemented through the opening in the middle stack trench 255. By etching intrinsic epi 120, intrinsic epi 120 is used as a sacrificial layer in the nanosheet stack 240B in which transistor 205B is to be formed. As a result of removing intrinsic epi 120 (and poly silicon 130) right side portions of the three SiGe 115 layers can remain suspended from the dielectric 140 material at the right side and be devoid of any material support beneath, above and to the left of them. The remaining three SiGe 115 structures can now form nanosheets 210B of the nanosheet stack 240B.

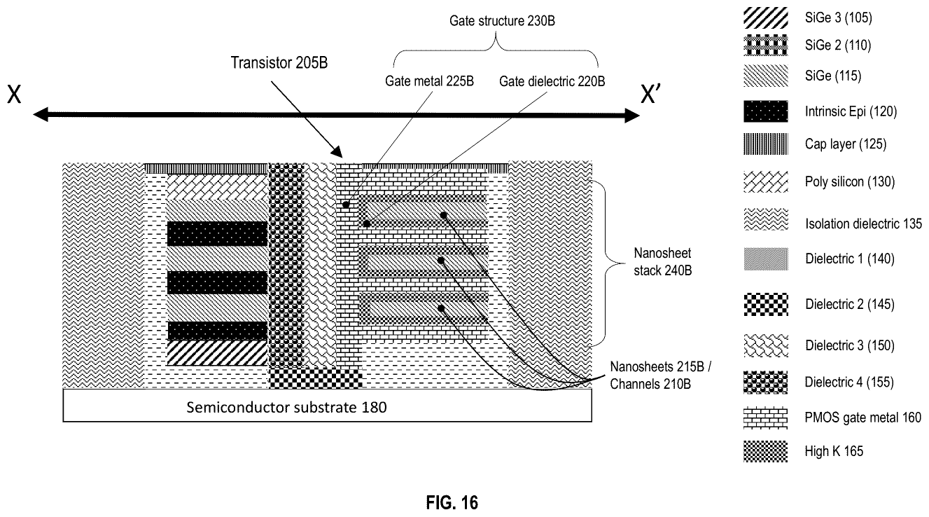

FIG. 16 illustrates a cross-sectional view of the layer stack in which the void left by the removed intrinsic epi 120 and poly silicon 130 is filled with a thin layer of high-k 165 material coated on the exposed surfaces of SiGe 115 nanosheets 215B, followed by a filling of PMOS gate metal 160 to form gate metal 225B. First, a layer of high-k 165 material can be selectively coated on the exposed surfaces of the SiGe 115 nanosheet 215B to create a gate dielectric 220. Once the nanosheets 215B are coated with high-k 160 to form gate dielectric 220B, PMOS gate metal 160 can fill the remainder of the void, above, below and in between the SiGe nanosheets 215B, which completes the gate structure 230B. High-k 165 material can include a high-k dielectric that has material properties and characteristics suitable for forming an effective PMOS transistor 205 and for interacting with PMOS gate metal 160. Likewise PMOS gate metal 160 can include properties and characteristics suitable for an PMOS gate metal 225 performance. At this point, channels 210B of transistor 205B are formed using nanosheets 215B and the PMOS transistor device 205B on the right side of the layer stack structure 250 is completed.

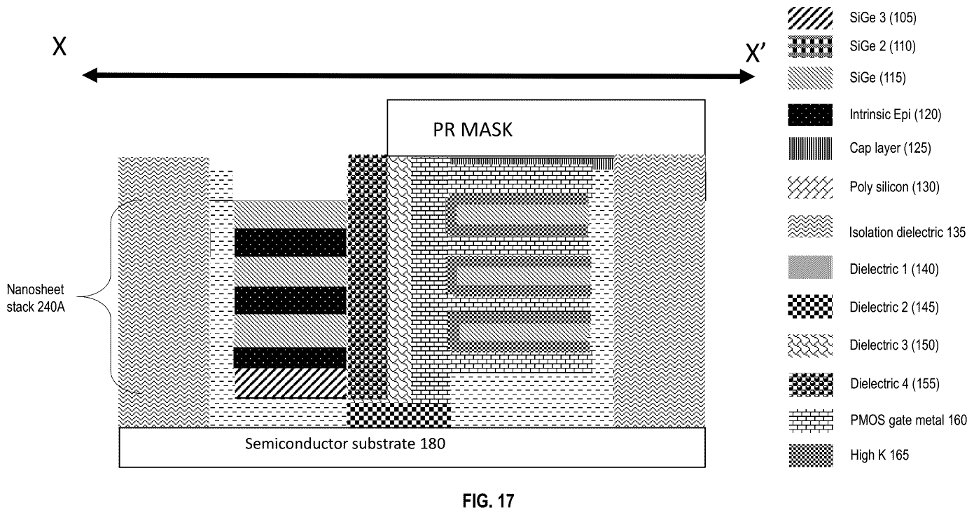

FIG. 17 illustrates a cross-sectional view of the layer stack in which a dielectric PR mask can be placed on the other side (e.g., right side) of the layer stack structure 250 in order to clear out the cap layer 125 and the poly silicon layer 130 on the left-side 3D nanosheet stack 240A. As a result a top layer of the SiGe 115 layer on the left-side nanosheet stack 240A can be exposed.

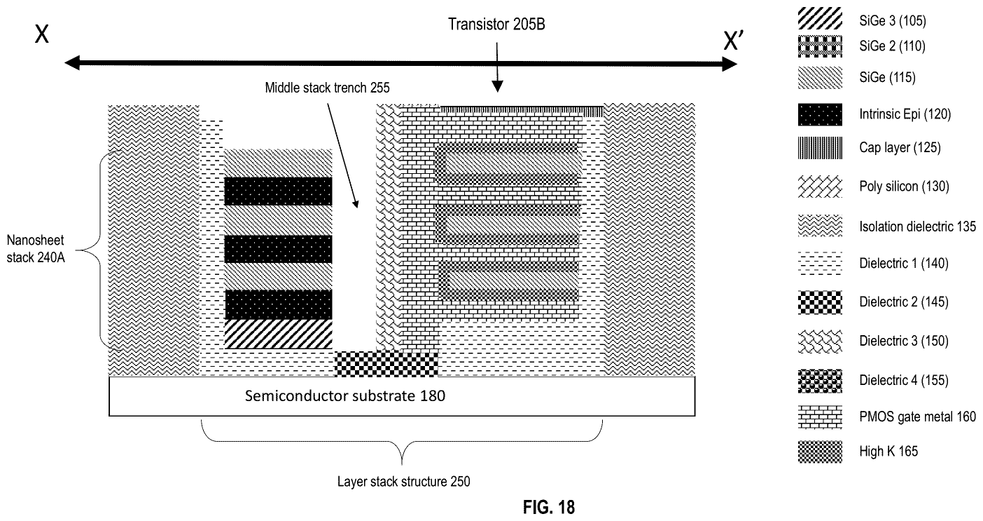

FIG. 18 illustrates a cross-sectional view of the layer stack structure 250 from which the PR mask can be removed. Then, dielectric 155 can be etched out from the middle stack trench 255 down to the dielectric 145 layer at the bottom of the middle stack trench 255. At the end of the etch, dielectric 145 and the SiGe 105 layer of the left-side 3D nanosheet stack 240A can be left exposed.

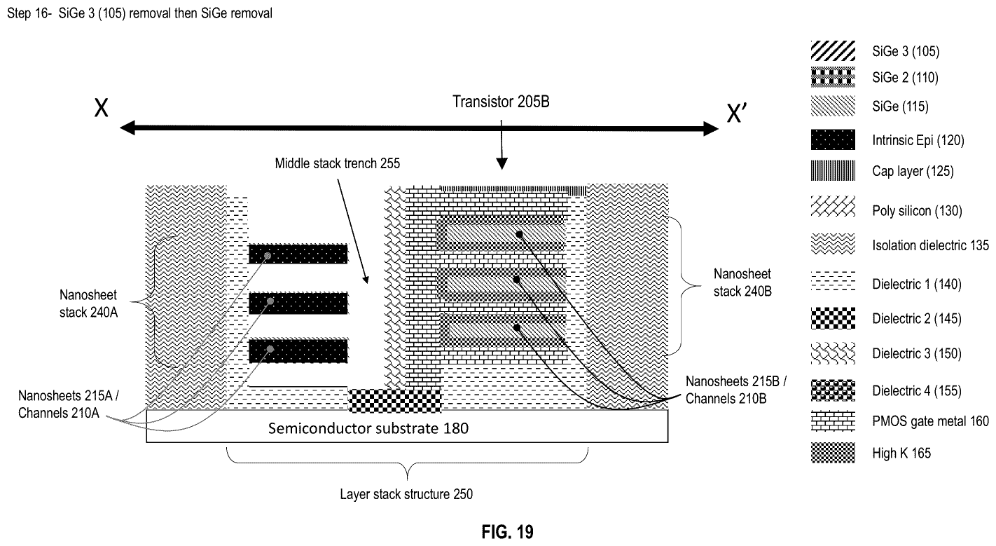

FIG. 19 illustrates a cross-sectional view of the layer stack structure 250 in which SiGe 105 and SiGe 115 layers can be removed. The removal of SiGe 105 and SiGe 115 layers can be completed through selective etches via the opening in the middle stack trench 255 made with the fabrication steps in connection with FIG. 18. Upon removal of SiGe 105 and SiGe 115 layers, horizontal suspended structures made from intrinsic epi 120 on the left side of the layer stack structure 250 can remain suspended from dielectric 140 on their left side and they can be without any material above, below, or to the right of them. The remaining three intrinsic epi 115 suspended horizontal structures can now form nanosheets 210A of the nanosheet stack 240A.

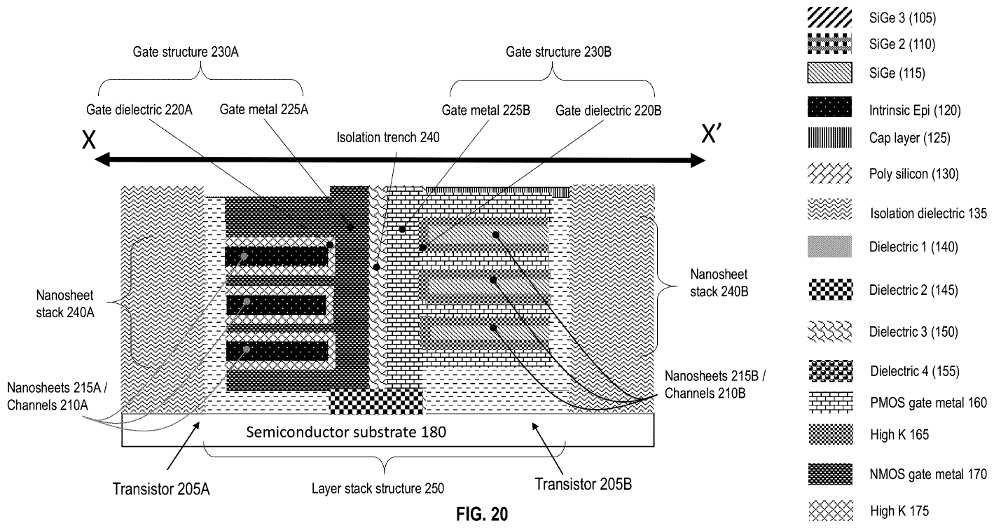

FIG. 20 illustrates a cross-sectional view of the layer stack structure 250 in which high-k 175 can be coated on nanosheets 215A to form gate dielectric 220A and NMOS gate metal 170 can be filled into the open space to form a gate metal 225A, thus completing an NMOS gate structure 230A. Similar to the fabrication steps performed in connection with FIG. 16 discussed in connection with transistor 205B formation, a coating of high-k 175 can be selectively deposited on all exposed surfaces of the intrinsic epi 120 nanosheets 215A to form gate dielectric 220A. On top of the high-k 175 deposited layer, NMOS gate metal 170 can be deposited so as to fill in the interior volume all around the intrinsic epi 120 nanosheets 215A and form the gate metal 220A. As a result gate structure 230A can surround intrinsic epi 120 nanosheets 215A from the top, bottom and side surfaces, just as with gate structure 230B and SiGe 115 nanosheets 215B in transistor 205B. High-k 175 material can include a high-k dielectric that has material properties and characteristics suitable for forming an effective NMOS transistor 205 and for interacting with NMOS gate metal 170. Likewise NMOS gate metal 170 can include properties and characteristics suitable for an NMOS gate metal 225 performance. At this point, channels 210A of transistor 205A are formed using nanosheets 215A and gate structure 230A is, thereby completing the formation of NMOS transistor 205A in the nanosheet stack 240A. After completing transistor 205A, CMP can be performed to remove the surplus material. At this point, transistors 205A and 205B are formed side-by-side and separated by the isolation trench 240.

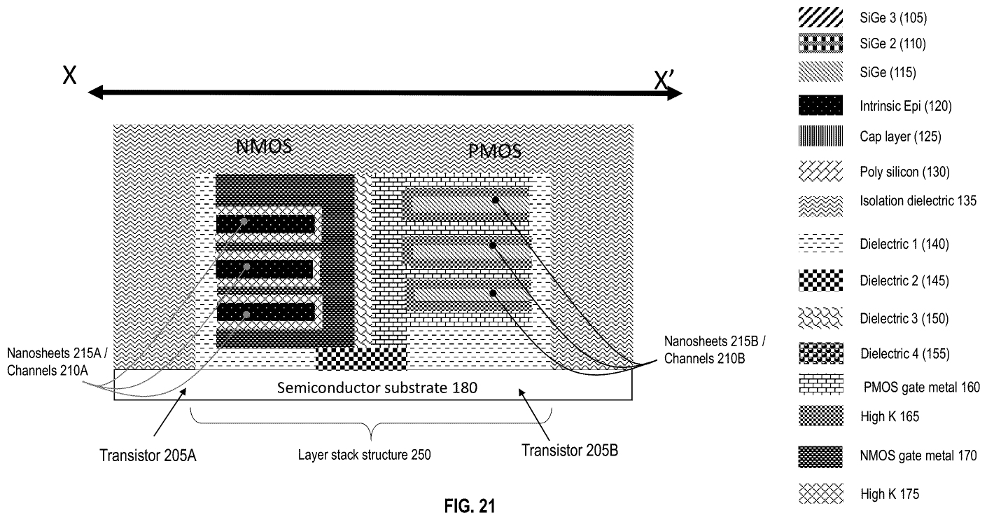

FIG. 21 illustrates a cross-sectional view of the layer stack structure 250 in transistor 205A and transistor 205B are covered with a layer of isolation dielectric 135 to electrically isolate the transistor structure 200 (e.g., transistors 205A and 205B) from other transistor structures 200. Upon completion of this step, CMP can be performed to remove any surplus material. The resulting layer stack structure 250 can include NMOS transistor 205A and PMOS transistor 205B along with all the features discussed earlier in connection with FIG. 1.

Each of the transistors 205A and 205B can further include a source structure and a drain structure (not illustrated). The source and drain structures can be located, for example, at two opposite ends of the channels 210 orthogonal to the plane of the cross-section illustrated in FIG. 22. For example, a source structure of transistor 205A can be connected to the channels 210A (e.g., nanosheets 215A) at a cross-sectional plane that is above and parallel to the cross-sectional plane illustrated in FIG. 22, while a drain structure of the transistor 205A can be connected to the channels 210A at a cross-section that is behind and parallel to the cross-sectional plane illustrated in FIG. 22. Similarly, a source structure of transistor 205B can be connected to the channels 210B (e.g., nanosheets 215B) at a cross-sectional plane that is above and parallel to the cross-sectional plane illustrated in FIG. 22, while a drain structure of the transistor 205B can be connected to the channels 210B at a cross-section that is behind and parallel to the cross-sectional plane illustrated in FIG. 22. It is understood that the locations of the source and drain structures can be swapped and that the source and drain structures can be connected to contacts on the top surface of the layer stack using metal vias and contacts. It is further understood that gate structures 230A and 230B can also be connected to the contacts on the top surface of the layer stack using metal vias and contacts.

Referring now to FIG. 22, illustrated is a flow diagram of an example method 2200 for fabricating side-by-side transistor structures using any combination of fabrication techniques and steps described in FIGS. 1-21. The method 2200 can include steps 2205-2230. At step 2205, the method forms a first channel with a first nanosheet. At step 2210, the method forms a second channel with a second nanosheet. At step 2215, the method forms a first gate structure of first transistor having first and second channels. At step 2220, the method forms a third channel with a third nanosheet. At step 2225, the method forms a fourth channel with a fourth nanosheet. At step 2230, the method forms a second gate structure with second transistor having third and fourth channels.

At step 2205, the method forms a first channel with a first nanosheet. The method can form a first channel of a first transistor using a first nanosheet oriented horizontally. The method can horizontally form the first nanosheet to form the first channel. The first transistor can be a first transistor of multiple transistors formed side-by-side. The first transistor can be an NMOS transistor. The first transistor can be a PMOS transistor. The first nanosheet can be a top horizontally oriented nanosheet of the first transistor. The first nanosheet can be formed from a horizontal layer of epitaxially grown material. The first nanosheet can be formed using SiGe layer of material. The first nanosheet can be formed using intrinsic epitaxially grown silicon (intrinsic epi) layer of material. The first channel can be formed using the first nanosheet. The first channel can be formed by selectively coating the nanosheet using high-k material. The first channel can be formed using the first nanosheet formed in the layer of material on one side of a layer material stack, while the same layer of material forming the first nanosheet in the first transistor is a sacrificial material on the other side of the layer material stack in the second transistor.

At step 2210, the method forms a second channel with a second nanosheet. The method can form a second channel of the first transistor using a second nanosheet oriented horizontally. The method can horizontally form the second nanosheet to form the second channel. The second nanosheet can include the same material as the first nanosheet, such as SiGe material or intrinsic epi layer of material. The second nanosheet can be disposed beneath the first nanosheet and can be vertically aligned with the first nanosheet. The second nanosheet can be spaced apart from the first nanosheet by a height defined by a layer of material that is used as sacrificial layer of material during the fabrication of the first transistor and where the same layer of material is used as the nanosheet in a transistor beside the first transistor (e.g., a second transistor).

The second nanosheet can be a bottom horizontally oriented nanosheet of the first transistor. The second nanosheet can be a second highest horizontally oriented nanosheet of the first transistor. The second channel can be formed using the second nanosheet. The second channel can be formed by selectively coating the nanosheet with high-k material. The second channel can be formed using the second nanosheet formed in the layer of material on one side of a layer material stack, while the same layer of material forming the second nanosheet in the first transistor is a sacrificial material on the other side of the layer material stack in the second transistor.

The method can include forming, using a fifth nanosheet of the first transistor, a fifth channel of the first transistor. The fifth nanosheet can be oriented horizontally. The method can vertically align the fifth nanosheet with the first nanosheet and with the second nanosheet of the first transistor. The fifth nanosheet can be disposed beneath the first and the second nanosheets and can be vertically aligned with the first and the second nanosheets.

At step 2215, the method forms a first gate structure of first transistor having first and second channels. The method can form a first gate structure of the first transistor where the first gate structure can be disposed between the first channel and the second channel. The first gate structure can be at least partly surrounding the first channel and the second channel. The first gate structure can include a first gate dielectric and a first gate metal. The first gate dielectric can include high-k material coated or layered on exposed surfaces of the nanosheets of the first transistor. The first gate metal can include metal that is deposited on top of the high-k material. The first gate metal can fill the voids in the first transistor between the nanosheets. For example, the first gate metal (and therefore the gate structure) can interface with or abut the top surface of the first nanosheet, the side surface of the first nanosheet and the bottom surface of the first nanosheet. For example, the first gate metal (and therefore the first gate structure) can interface with or abut the top surface of the second nanosheet, the side surface of the second nanosheet and the bottom surface of the second nanosheet.

The method can form a first gate dielectric of the first gate structure. The first gate dielectric can be disposed between the first nanosheet and a first gate metal of the first gate structure. The method can form the first gate dielectric disposed between the second nanosheet and the first gate metal. The method can form the first gate structure disposed between the fifth channel and the second channel. The first gate structure can at least partly surrounding the fifth channel. For example, the first gate metal (and therefore the first gate structure) can interface with or abut the top surface of the fifth nanosheet, the side surface of the fifth nanosheet and the bottom surface of the fifth nanosheet.

At step 2220, the method forms a third channel of a second transistor with a third nanosheet. The method can form, using a third nanosheet oriented horizontally, a third channel of the second transistor. The second transistor can be disposed beside the first transistor. The second transistor can be an NMOS transistor. The second transistor can be a PMOS transistor. The third nanosheet can be a top horizontally oriented nanosheet of the second transistor.

The third nanosheet can be formed from a horizontal layer of epitaxially grown material. The third nanosheet can be formed using SiGe layer or intrinsic epi material. The third channel can be formed using the third nanosheet. The third channel can be formed by selectively coating the nanosheet using high-k material. The third channel can be formed using the third nanosheet formed in the layer of material on one side of a layer material stack, while the same layer of material forming the third nanosheet in the second transistor is a sacrificial material on the other side of the layer material stack in the first transistor.

The method can form the third nanosheet of the second transistor in a horizontal alignment with a portion of the first gate structure of the first transistor that is disposed between the first channel and the second channel. For example, the third nanosheet (and third channel) can be horizontally aligned with a layer of first gate metal of the first transistor that is disposed between the first nanosheet (and the first channel) and the second nanosheet (and the second channel) of the first transistor. For example, the third nanosheet can be disposed in a horizontal plane that extends through a region between the first nanosheet and the second nanosheet of the first transistor. The first nanosheet of the first transistor can be disposed in a horizontal plane that extends through a region above the third nanosheet of the second transistor. The second nanosheets of the first transistor can be disposed in a horizontal plane that extends through a region below the third nanosheet of the second transistor.

At step 2225, the method forms a fourth channel with a fourth nanosheet. The method can form, using a fourth nanosheet oriented horizontally, a fourth channel of the second transistor. The fourth nanosheet can include the same material as the third nanosheet, such as SiGe material or intrinsic epi material. The fourth nanosheet can be disposed beneath the third nanosheet and can be vertically aligned with the third nanosheet. The fourth nanosheet can be spaced apart from the third nanosheet by a height defined by a layer of material that is used as sacrificial layer of material during the fabrication of the first transistor and where the same layer of material is used as the nanosheet in a transistor beside the second transistor (e.g., in the first transistor).

The fourth nanosheet can be a bottom horizontally oriented nanosheet of the second transistor. The fourth nanosheet can be a second highest horizontally oriented nanosheet of the second transistor. The fourth channel can be formed using the fourth nanosheet. The fourth channel can be formed by selectively coating the fourth nanosheet with high-k material. The fourth channel can be formed using the fourth nanosheet formed in the layer of material on one side of a layer material stack, while the same layer of material forming the fourth nanosheet in the second transistor is a sacrificial material on the other side of the layer material stack in the first transistor.

The method can include forming, using a sixth nanosheet of the second transistor, a sixth channel of the second transistor. The sixth nanosheet can be oriented horizontally. The sixth nanosheet can be disposed beneath the third nanosheet and the fourth nanosheet. The sixth nanosheet can be vertically aligned with the third nanosheet and the fourth nanosheet.

The method can include forming the second nanosheet of the first transistor in a horizontal alignment with a portion of the second gate structure of the second transistor disposed between the third channel and the fourth channel. For example, the second nanosheet (and second channel) of the first transistor can be horizontally aligned with a layer of second gate metal of the second transistor that is disposed between the third nanosheet (and the third channel) and the fourth nanosheet (and the fourth channel) of the second transistor. For example, the second nanosheet can be disposed in a horizontal plane that extends through a region between the third nanosheet and the fourth nanosheet of the second transistor. The third nanosheet of the second transistor can be disposed in a horizontal plane that extends through a region above the second nanosheet of the first transistor. The fourth nanosheets of the second transistor can be disposed in a horizontal plane that extends through a region below the second nanosheet of the first transistor.

The first, the second, the third, the fourth, the fifth and the sixth nanosheets can each be disposed at different heights. In a first transistor, the first nanosheet can be disposed above the second nanosheet and the second nanosheet can be disposed above the fifth nanosheet. In a second transistor, the third nanosheet can be disposed above the fourth nanosheet and the fourth nanosheet can be disposed above the sixth nanosheet. Additionally or alternatively, the first nanosheet of the first transistor can be disposed above the third nanosheet of the second transistor. The third nanosheet of the second transistor can be disposed above the second nanosheet of the first transistor. The second nanosheet of the first transistor can be disposed above the fourth nanosheet of the second transistor. The fourth nanosheet of the second transistor can be disposed above the fifth nanosheet of the first transistor. The fifth nanosheet of the first transistor can be disposed above the sixth nanosheet of the second transistor.

At step 2230, the method forms a second gate structure with second transistor having third and fourth channels. The method can include forming a second gate structure of the second transistor. The second gate structure can be disposed between the third channel and the fourth channel. The second gate structure can be at least partly surrounding the first channel and the second channel. The second gate structure can include all the functionality of the first gate structure discussed in connection with step 2215.

The second gate structure can include a second gate dielectric and a second gate metal. The second gate dielectric can include high-k material coated or layered on exposed surfaces of the nanosheets of the second transistor. The second gate metal can include metal that is deposited on top of the high-k material. The second gate metal can fill the voids in the second transistor between the nanosheets. For example, the second gate metal (and therefore the gate structure) can interface with or abut the top surface of the third nanosheet, the side surface of the third nanosheet and the bottom surface of the third nanosheet. For example, the second gate metal (and therefore the second gate structure) can interface with or abut the top surface of the fourth nanosheet, the side surface of the fourth nanosheet and the bottom surface of the fourth nanosheet.

The method can include forming the second gate structure disposed between the sixth channel and the fourth channel and at least partly surrounding the sixth channel. The method can include forming a second gate dielectric of the second gate structure. The second dielectric can be disposed between the third nanosheet and a second gate metal of the second gate structure. The method can form the second gate dielectric disposed between the fourth nanosheet and the second gate metal.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features described only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A transistor structure comprising:
a first transistor, comprising:
a first nanosheet oriented horizontally and forming a first channel;
a second nanosheet oriented horizontally and forming a second channel; and
a first gate structure disposed between and at least partly surrounding the first channel and the second channel; and
a second transistor disposed beside the first transistor, the second transistor comprising:
a third nanosheet oriented horizontally and forming a third channel;
a fourth nanosheet oriented horizontally and forming a fourth channel; and
a second gate structure disposed between and at least partly surrounding the third channel and the fourth channel, wherein the third nanosheet is disposed in a plane that is between a plane in which the first nanosheet is disposed and a plane in which the second nanosheet is disposed, and the fourth nanosheet is disposed in a plane that is beneath the plane in which the second nanosheet is disposed.

2. The transistor structure of claim 1, wherein:
the first nanosheet of the first transistor is disposed above and vertically aligned with the second nanosheet of the first transistor; and
the third nanosheet of the second transistor is disposed above and vertically aligned with the fourth nanosheet of the second transistor.

3. The transistor structure of claim 1, wherein:
the first transistor further includes:
a fifth nanosheet forming a fifth channel, the fifth nanosheet disposed in a plane that is below the plane in which the second nanosheet is disposed, the fifth nanosheet oriented horizontally and vertically aligned with the first nanosheet and with the second nanosheet; and
the first gate structure disposed between the fifth channel and the second channel and at least partly surrounding the fifth channel.

4. The transistor structure of claim 3, wherein:
the second transistor further includes:
a sixth nanosheet forming a sixth channel, the sixth nanosheet disposed in a plane that is below the plane in which the fourth nanosheet is disposed, the sixth nanosheet oriented horizontally and vertically aligned with the third nanosheet and the fourth nanosheet; and
the second gate structure disposed between the sixth channel and the fourth channel and at least partly surrounding the sixth channel.

5. The transistor structure of claim 1, further comprising:
a first gate dielectric of the first gate structure of the first transistor disposed between the first nanosheet and a first gate metal of the first gate structure; and
the first gate dielectric disposed between the second nanosheet and the first gate metal.

6. The transistor structure of claim 5, further comprising:
a second gate dielectric of the second gate structure of the second transistor disposed between the third nanosheet and a second gate metal of the second gate structure; and
the second gate dielectric disposed between the fourth nanosheet and the second gate metal.

7. The transistor structure of claim 1, wherein the third nanosheet of the second transistor is horizontally aligned with a portion of the first gate structure of the first transistor that is disposed between the first channel and the second channel.

8. The transistor structure of claim 7, wherein the second nanosheet of the first transistor is horizontally aligned with a portion of the second gate structure of the second transistor that is disposed between the third channel and the fourth channel.

9. The transistor structure of claim 1, wherein the first transistor is one of a p-type metal oxide semiconductor (PMOS) transistor and an n-type metal oxide semiconductor (NMOS) transistor and the second transistor is a remaining one of the PMOS transistor and the NMOS transistor.

10. The transistor structure of claim 1, wherein the first transistor and the second transistor are one of an NMOS transistor or a PMOS transistor.

11. The transistor structure of claim 1, wherein:
the first nanosheet includes a shape of a rectangular prism and the first gate structure abutting at least a portion of a top surface of the first nanosheet, a portion of a bottom surface of the first nanosheet, and at least a portion of a side surface of the first nanosheet; and
the second nanosheet includes the shape of the rectangular prism and the first gate structure abutting at least a portion of a top surface of the second nanosheet, a portion of a bottom surface of the second nanosheet, and at least a portion of a side surface of the second nanosheet.

12. The transistor structure of claim 1, further comprising:
a dielectric structure extending in a vertical trench between the first transistor and the second transistor to electrically isolate the first gate structure of the first transistor from the second gate structure of the second transistor.

13. A method comprising:
forming a first transistor by:
horizontally forming a first nanosheet to form a first channel;
horizontally forming a second nanosheet to form a second channel of the first transistor;
forming a first gate structure, the first gate structure disposed between the first channel and the second channel and at least partly surrounding the first channel and the second channel;
forming a second transistor by:
horizontally forming a third nanosheet to form a third channel disposed beside the first transistor;
horizontally forming a fourth nanosheet to form a fourth channel; and
forming a second gate structure, the second gate structure disposed between the third channel and the fourth channel and at least partly surrounding the first channel and the second channel, wherein the third nanosheet is disposed in a plane that is between a plane in which the first nanosheet is disposed and a plane in which the second nanosheet is disposed, and the fourth nanosheet is disposed in a plane that is beneath the plane in which the second nanosheet is disposed.

14. The method of claim 13, wherein:
forming the first transistor includes:
disposing the first nanosheet above the second nanosheet;
vertically aligning the first nanosheet with the second nanosheet; and
forming the second transistor includes:
disposing the third nanosheet above the fourth nanosheet; and
vertically aligning the third nanosheet with the fourth nanosheet.

15. The method of claim 13, wherein:
forming the first transistor further includes:
horizontally forming a fifth nanosheet to form a fifth channel, the fifth nanosheet disposed in a plane that is beneath the plane in which the second nanosheet is disposed;
vertically aligning the fifth nanosheet with the first nanosheet and with the second nanosheet; and
wherein forming the first gate structure further includes forming the first gate structure between the fifth channel and the second channel and at least partly surrounding the fifth channel.

16. The method of claim 15, wherein:
forming the second transistor further includes:
horizontally forming a sixth nanosheet to form a sixth channel, the sixth nanosheet disposed in a plane that is beneath the plane in which the fourth nanosheet is disposed;
vertically aligning the sixth nanosheet with the third nanosheet and the fourth nanosheet; and
wherein forming the second gate structure further includes forming the second gate structure between the sixth channel and the fourth channel and at least partly surrounding the sixth channel.

17. The method of claim 13, further comprising:
forming a first gate dielectric of the first gate structure, the first gate dielectric disposed between the first nanosheet and a first gate metal of the first gate structure; and
forming the first gate dielectric disposed between the second nanosheet and the first gate metal.

18. The method of claim 17, further comprising:
forming a second gate dielectric of the second gate structure, the second dielectric disposed between the third nanosheet and a second gate metal of the second gate structure; and
forming the second gate dielectric disposed between the fourth nanosheet and the second gate metal.

19. The method of claim 13, wherein:
forming the third nanosheet of the second transistor includes forming the third nanosheet in a horizontal alignment with a portion of the first gate structure of the first transistor disposed between the first channel and the second channel.

20. The method of claim 19, wherein:
forming the second nanosheet of the first transistor includes forming the second nanosheet in a horizontal alignment with a portion of the second gate structure of the second transistor disposed between the third channel and the fourth channel.
